(19) United States
(12) Patent Application Publication
(10) Pub. No.: US 2025/0393232 A1
(43) Pub. Date: Dec. 25, 2025

(54) METHOD OF MANUFACTURING STACKED NANOSHEET GATE-ALL-AROUND FIELD-EFFECT TRANSISTOR AND FIELD-EFFECT TRANSISTOR

(71) Applicant: INSTITUTE OF MICROELECTRONICS, CHINESE ACADEMY OF SCIENCES, Beijing (CN)

(72) Inventors: Qingzhu ZHANG, Beijing (CN); Meihe ZHANG, Beijing (CN); Lianlian LI, Beijing (CN); Qingkun LI, Beijing (CN); Xinghua WANG, Beijing (CN); Lei CAO, Beijing (CN); Guanqiao SANG, Beijing (CN); Renjie JIANG, Beijing (CN); Peng WANG, Beijing (CN); Huaxiang YIN, Beijing (CN)

(21) Appl. No.: 19/002,395

(22) Filed: Dec. 26, 2024

(30) Foreign Application Priority Data
Jun. 21, 2024 (CN) 202410814338.4

(51) Int. Cl. H10D 30/01; H10D 30/00; H10D 64/01

(52) U.S. Cl. CPC H10D 30/0191; H10D 30/0196; H10D 30/502; H10D 64/017

(57) ABSTRACT

The present disclosure provides a method of manufacturing a stacked nanosheet gate-all-around field-effect transistor and a field-effect transistor. The method includes: forming a stack on a substrate, the stack includes multiple nanosheet layers and multiple silicon alloy layers alternately stacked; etching each silicon alloy layer to form a first cavity, the first cavity is between two adjacent nanosheet layers; manufacturing a protective layer in the first cavity, the protective layer covers an inner surface of the first cavity and is recessed to form a second cavity; manufacturing a gate electrode and two source/drain electrodes based on the second cavity, an air spacer is between the gate electrode and any source/drain electrode; and removing a first dielectric constant medium in a first space, the first space is in the air spacer and surrounded by an upper surface of the uppermost nanosheet layer, the gate electrode and any source/drain electrode.

### CROSS REFERENCE TO RELATED APPLICATION

This application claims priority to Chinese Patent Application No. 202410814338.4, filed on Jun. 21, 2024, the entire content of which is incorporated herein in its entirety by reference.

### TECHNICAL FIELD

The present disclosure relates to a field of semiconductor technology, and more specifically, to a method of manufacturing a stacked nanosheet gate-all-around field-effect transistor and a field-effect transistor.

### BACKGROUND

With a continuous miniaturization of a size of an integrated circuit, a traditional planar metal-oxide semiconductor field-effect transistor and a traditional fin field-effect transistor (FinFET) have successively reached a physical limit. For a technology node of below 3 nm, a gate-all-around field-effect transistor (GAAFET) has become a key structure for a further size miniaturization due to its excellent gate control performance and good compatibility with a FinFET process. A nanosheet GAAFET (NS GAAFET) in the GAAFET is a common device structure in a gate-all-around device with a technology node of below 3 m.

However, in the related art, the NS GAAFET has a complex device structure and a large parasitic capacitance, which is one of the most important factors that limit an improvement of its circuit working speed.

The above-mentioned statements are only used to provide background technology information related to the present disclosure and do not necessarily constitute the related art.

### SUMMARY

In order to provide a basic understanding of some aspects of the embodiments of the present disclosure, a summary is given below. The summary is not a general comment, nor is it intended to determine key/important elements or delineate the scope of protection of these embodiments. The sole purpose is to present some concepts in a simple form as a preface to the detailed descriptions later.

According to an aspect of the embodiments of the present disclosure, a method of manufacturing a stacked nanosheet gate-all-around field-effect transistor is provided, including:
forming a stack on a substrate by deposition, where the stack includes a plurality of silicon material nanosheet layers and a plurality of silicon alloy layers alternately stacked;
etching each of the plurality of silicon alloy layers to form a first pull-back cavity, where the first pull-back cavity is located between two adjacent silicon material nanosheet layers;
manufacturing a protective layer in the first pull-back cavity, where the protective layer covers an inner surface of the first pull-back cavity, and the protective layer is recessed to form a second pull-back cavity;
manufacturing a gate electrode located on the substrate and two source/drain electrodes located on the substrate based on the second pull-back cavity, where an air spacer is formed between the gate electrode and any one of the source/drain electrodes; and
removing a first dielectric constant medium in a first space, where the first space is in the air spacer, and the first space is a space surrounded by an upper surface of the uppermost silicon material nanosheet layer, the gate electrode and any one of the source/drain electrodes.

According to some embodiments of the present disclosure, the forming a stack on a substrate by deposition includes:
providing a silicon substrate, and sequentially performing well lithography, ion implantation and annealing on the silicon substrate; and
forming the stack on a surface of the annealed silicon substrate by deposition.

According to some embodiments of the present disclosure, the manufacturing a gate electrode located on the substrate and two source/drain electrodes located on the substrate based on the second pull-back cavity includes:
manufacturing two solid spacers, a first source/drain electrode, a second source/drain electrode and the gate electrode, where the plurality of silicon material nanosheet layers are located between the two solid spacers, and the second pull-back cavity is filled with a corresponding solid spacer; and
removing the two solid spacers to form two air spacers.

According to some embodiments of the present disclosure, the manufacturing two solid spacers includes:
depositing an amorphous silicon film on the substrate;

forming a target pattern on the amorphous silicon film by photoetching;
forming a hard mask layer on the amorphous silicon film with the target pattern by deposition; and
etching the amorphous silicon film formed with the hard mask layer to form the two solid spacers.

According to some embodiments of the present disclosure, the manufacturing a first source/drain electrode, a second source/drain electrode and the gate electrode includes: removing the hard mask layer by anisotropic etching to obtain a plurality of fin structures;
filling an insulating medium between adjacent fin structures, such that a shallow trench isolation is formed between the adjacent fin structures;
removing a recess of the shallow trench isolation; and
etching the fin structure to obtain the first source/drain electrode, the second source/drain electrode and the gate electrode.

According to some embodiments of the present disclosure, the etching the fin structure to obtain the first source/drain electrode, the second source/drain electrode and the gate electrode includes:
sequentially forming an insulating layer and a silicon layer on a surface of the uppermost silicon material nanosheet layer in the fin structure by deposition;
etching the silicon layer to form a dummy gate structure;
manufacturing a spacer structure and a source/drain region on two sides of the dummy gate structure;
forming the first source/drain electrode and the second source/drain electrode on the source/drain region;
removing the dummy gate structure to form a gate electrode region;
removing the silicon alloy layer in the stack to release a nanosheet channel; and
forming the gate electrode in the gate electrode region by deposition.

According to some embodiments of the present disclosure, the manufacturing a spacer structure on two sides of the dummy gate structure includes:
depositing a spacer isolation dielectric film; and
forming the spacer structure on a surface of the spacer isolation dielectric film by etching.

According to some embodiments of the present disclosure, the method further includes: removing the protective layer.

According to some embodiments of the present disclosure, the method further includes:
forming an isolation layer by deposition, where the isolation layer covers the air spacer;
etching the isolation layer to form a contact hole; and
depositing a tungsten material in the contact hole to form a tungsten plug.

According to some embodiments of the present disclosure, the protective layer is an amorphous carbon layer.

According to another aspect of the embodiments of the present disclosure, a stacked nanosheet gate-all-around field-effect transistor is provided, manufactured by the method described in any one of the embodiments of the present disclosure, including:
a substrate;
a first source/drain electrode located on the substrate and a second source/drain electrode located on the substrate;
a gate electrode located on the substrate and located between the first source/drain electrode and the second source/drain electrode, where an air spacer is formed between the gate electrode and the first source/drain electrode and between the gate electrode and the second source/drain electrode; and
a plurality of silicon material nanosheet layers spaced apart from each other in the gate electrode, where each of the plurality of silicon material nanosheet layers is connected to the first source/drain electrode and the second source/drain electrode, and each of the plurality of silicon material nanosheet layers is parallel to an upper surface of the substrate.

The above-mentioned descriptions are only an overview of the technical solutions of the embodiments of the present disclosure. In order to understand the technical means of the embodiments of the present disclosure more clearly, it may be implemented according to the contents of the specification. In order to make the above and other objectives, features and advantages of the embodiments of the present disclosure more obvious and understandable, specific embodiments of the present disclosure will be described below.

### BRIEF DESCRIPTION OF THE DRAWINGS

In order to clearly describe the technical solutions in the embodiments of the present disclosure or in the related art, accompanying drawings required in the descriptions of the embodiments or the related art will be briefly introduced below. Obviously, the accompanying drawings in the following descriptions are only accompanying drawings for some embodiments of the present disclosure, and other accompanying drawings may be obtained according to these accompanying drawings by those skilled in the art without any creative work.

FIG. 1 shows a schematic diagram of a three-dimensional structure of a stacked nanosheet gate-all-around field-effect transistor according to an embodiment of the present disclosure.

FIG. 2 shows a cross-sectional view of a stacked nanosheet gate-all-around field-effect transistor according to an embodiment of the present disclosure taken along a line X-X′.

FIG. 3 shows a cross-sectional view of a stacked nanosheet gate-all-around field-effect transistor according to an embodiment of the present disclosure taken along a line Y-Y′.

FIG. 4 shows a flowchart of a method of manufacturing a stacked nanosheet gate-all-around field-effect transistor according to an embodiment of the present disclosure.

FIG. 5 shows a cross-sectional view of a structure obtained after performing each of steps (a) to (d) in a manufacturing method according to another embodiment of the present disclosure taken along a line X-X′.

FIG. 6 shows a cross-sectional view of a structure obtained after performing each of steps (a) to (d) in a manufacturing method according to another embodiment of the present disclosure taken along a line Y-Y′.

FIG. 7 shows a cross-sectional view of a structure obtained after performing each of steps (e) to (h) in a manufacturing method according to another embodiment of the present disclosure taken along a line X-X′.

FIG. 8 shows a cross-sectional view of a structure obtained after performing each of steps (e) to (h) in a manufacturing method according to another embodiment of the present disclosure taken along a line Y-Y′.

FIG. 9 shows a cross-sectional view of a structure obtained after performing each of steps (i) to (1) in a manufacturing method according to another embodiment of the present disclosure taken along a line X-X′.

FIG. 10 shows a cross-sectional view of a structure obtained after performing each of steps (i) to (1) in a manufacturing method according to another embodiment of the present disclosure taken along a line Y-Y′.

FIG. 11 shows a cross-sectional view of a structure obtained after performing each of steps (m) to (p) in a manufacturing method according to another embodiment of the present disclosure taken along a line X-X′.

FIG. 12 shows a cross-sectional view of a structure obtained after performing each of steps (m) to (p) in a manufacturing method according to another embodiment of the present disclosure taken along a line Y-Y′.

FIG. 13 shows a cross-sectional view of a structure obtained after performing each of steps (q) to (t) in a manufacturing method according to another embodiment of the present disclosure taken along a line X-X′.

FIG. 14 shows a cross-sectional view of a structure obtained after performing each of steps (q) to (t) in a manufacturing method according to another embodiment of the present disclosure taken along a line Y-Y′.

FIG. 15 shows a cross-sectional view of a structure obtained after performing each of steps (u) to (y) in a manufacturing method according to another embodiment of the present disclosure taken along a line X-X′.

FIG. 16 shows a cross-sectional view of a structure obtained after performing each of steps (u) to (y) in a manufacturing method according to another embodiment of the present disclosure taken along a line Y-Y′.

### DETAILED DESCRIPTION OF EMBODIMENTS

In order to make objectives, technical solutions and advantages of the present disclosure clearer, the present disclosure will be further described in combination with the accompanying drawings and specific embodiments. It should be understood that the specific embodiments described herein are only used to illustrate the present disclosure, and are not intended to limit the present disclosure. Based on the embodiments of the present disclosure, all other embodiments obtained by those skilled in the art without any creative work fall within the scope of protection of the present disclosure.

It may be understood by those skilled in the art that all terms (including technical and scientific terms) used herein have meanings generally understood by those of ordinary skilled in the art, unless otherwise defined. It should also be understood that the terms, such as those defined in general dictionaries, should be interpreted as having the meaning consistent with the context of the related art, and should not be interpreted in an idealized or overly formal manner unless they are specifically defined as here.

GAAFET includes a nanowire structure (NW GAAFET) and a nanosheet structure (NS GAAFET). The nanosheet structure may obtain a larger driving current per unit projection area than the nanowire structure, so the NS GAAFET becomes a device structure in a gate-all-around device with a technology node of below 3 nm.

A parasitic capacitance of the NS GAAFET mainly includes: a capacitance (C_{gs/d}) between a gate electrode and a source/drain electrode, a capacitance (C_{gb}) between the gate electrode and a substrate, and a parasitic capacitance (C_{cr,pr}) at an inner spacer outside adjacent nanosheets. C_{gs/d} is a main portion of the parasitic capacitance because of a large area between the gate electrode and the source/drain electrode and a thin dielectric layer.

C_{gs/d} is not only affected by an overlapping area of the gate electrode and a source/drain epitaxial region as well as an overlapping area of the gate electrode and the source/drain electrode, but also affected by factors such as a dielectric constant value, a dielectric layer width, etc. of the dielectric between the gate electrode and the source/drain epitaxial region as well as between the gate electrode and the source/drain electrode. A large C_{gs/d} is provided at a spacer position of the NS GAAFET. At this position, SiNₓ and HfO₂ (K_{siO2}≈3.9) are provided between the gate electrode and the source/drain epitaxial region, and SiO₂, SiNₓ and HfO₂ are provided between the gate electrode and the source/drain electrode. The HfO₂ material has the maximum K value, resulting in a large parasitic capacitance at the spacer position, thereby affecting a working speed of a device and a circuit.

A method of manufacturing a stacked nanosheet gate-all-around field-effect transistor and a field-effect transistor provided by the embodiments of the present disclosure will be described below with reference to the accompanying drawings.

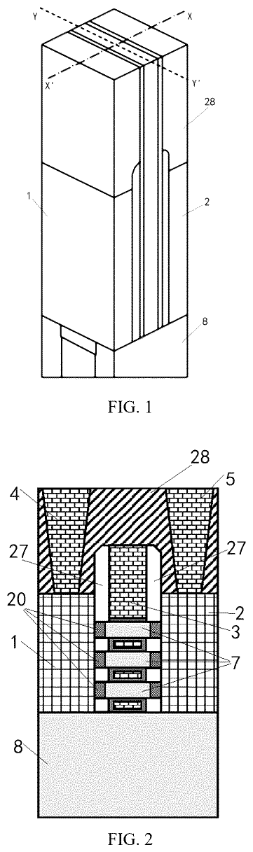

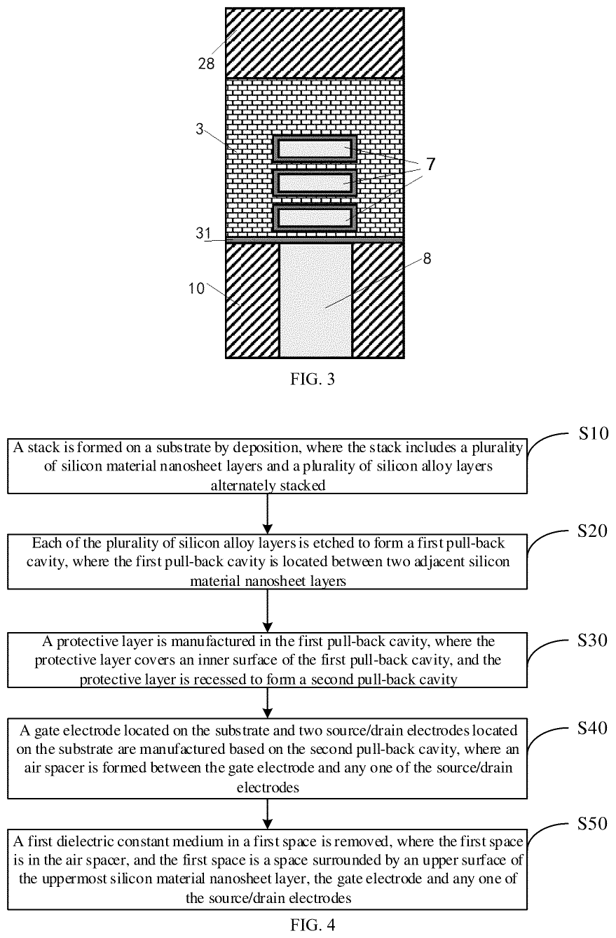

Referring to FIG. 1 to FIG. 3, an embodiment of the present disclosure provides a stacked nanosheet gate-all-around field-effect transistor, including: a substrate 8; a first source/drain electrode 1 located on the substrate 8 and a second source/drain electrode 2 located on the substrate 8; a gate electrode 3 located on the substrate 8 and located between the first source/drain electrode 1 and the second source/drain electrode 2, where an air spacer 27 is formed between the gate electrode 3 and the first source/drain electrode 1 and between the gate electrode 3 and the second source/drain electrode 2; and a plurality of silicon material nanosheet layers 7 spaced apart from each other in the gate electrode 3, where each of the plurality of silicon material nanosheet layers 7 is connected to the first source/drain electrode 1 and the second source/drain electrode 2, and each of the plurality of silicon material nanosheet layers 7 is parallel to an upper surface of the substrate 8. A portion of the silicon material nanosheet layer 7 connected to the first source/drain electrode 1 is located outside the gate electrode 3. A portion of the silicon material nanosheet layer 7 connected to the second source/drain electrode 2 is located outside the gate electrode 3. Lines X-X′ and Y-Y′ are shown in FIG. 1.

Each silicon material nanosheet layer 7 is connected to the first source/drain electrode 1 and the second source/drain electrode 2 through an epitaxial layer 20.

Since air has the lowest dielectric constant, the air spacer 27 may greatly reduce the parasitic capacitance.

In some embodiments, the stacked nanosheet gate-all-around field-effect transistor may further include:
a first insulating layer 28 covering the gate electrode 3, the first source/drain electrode 1 and the second source/drain electrode 2; a first contact electrode 4 provided in the first insulating layer 28, and having a first end in contact with the first source/drain electrode 1 and a second end exposed from a top surface of the first insulating layer 28; and a second contact electrode 5 provided in the first insulating layer 28, and having a first end in contact with the second source/drain electrode 2 and a second end exposed from the top surface of the first insulating layer 28.

For example, the stacked nanosheet gate-all-around field-effect transistor further includes: an amorphous silicon layer 31 located between the gate electrode 3 and the substrate 8.

The stacked nanosheet gate-all-around field-effect transistor in the embodiments of the present disclosure has a simple structure, a small parasitic capacitance, and a high working speed.

A high dielectric constant (High-K) material is provided in a portion of the air spacer 27 located between two adjacent epitaxial layers 20. Such High-K material may increase a driving current of the field-effect transistor and reduce an on-resistance of the field-effect transistor, thereby optimizing a performance of a circuit composed of the field-effect transistor, such as reducing an inverter delay, increasing a frequency of a ring oscillator circuit, etc.

Referring to FIG. 4, another embodiment of the present disclosure provides a method of manufacturing a stacked nanosheet gate-all-around field-effect transistor in any one of the above-mentioned embodiments, which may include steps S10 to S50.

In S10, a stack is formed on a substrate by deposition, where the stack includes a plurality of silicon material nanosheet layers and a plurality of silicon alloy layers alternately stacked.

For example, forming a stack on a substrate by deposition may include: providing a silicon substrate, and sequentially performing well lithography, ion implantation and annealing on the silicon substrate; and forming the stack on a surface of the annealed silicon substrate by deposition.

In S20, each of the plurality of silicon alloy layers is etched to form a first pull-back cavity, where the first pull-back cavity is located between two adjacent silicon material nanosheet layers.

Specifically, two ends of the silicon alloy layer are etched to etch off a portion of the silicon alloy layer, so as to form a recess portion between the two adjacent silicon material nanosheet layers. The recess portion is the first pull-back cavity.

In S30, a protective layer is manufactured in the first pull-back cavity, where the protective layer covers an inner surface of the first pull-back cavity, and the protective layer is recessed to form a second pull-back cavity.

Specifically, the protective layer may be an amorphous carbon layer. A thickness of the protective layer is less than half of an etching depth when etching the silicon alloy layer to form the first pull-back cavity.

The amorphous carbon layer may be deposited in the first pull-back cavity to form the protective layer, and a recess portion on the protective layer forms the second pull-back cavity. The protective layer is used to protect the High-K material from being removed. The High-K material may increase a driving current per unit projection area, thereby reducing the on-resistance of the field-effect transistor and optimizing the performance of the circuit composed of the field-effect transistor, such as reducing the inverter delay, increasing the frequency of the ring oscillator circuit, etc.

In S40, a gate electrode located on the substrate and two source/drain electrodes located on the substrate are manufactured based on the second pull-back cavity, where an air spacer is formed between the gate electrode and any one of the source/drain electrodes.

The two source/drain electrodes are called a first source/drain electrode and a second source/drain electrode. For example, manufacturing a gate electrode located on the substrate and two source/drain electrodes located on the substrate based on the second pull-back cavity may include: manufacturing two solid spacers, a first source/drain electrode, a second source/drain electrode and the gate electrode, where the plurality of silicon material nanosheet layers are located between the two solid spacers, and the second pull-back cavity is filled with a corresponding solid spacer; and removing the two solid spacers to form two air spacers.

For example, manufacturing two solid spacers may include: depositing an amorphous silicon film on the substrate; forming a target pattern on the amorphous silicon film by photoetching; forming a hard mask layer on the amorphous silicon film with the target pattern by deposition; and etching the amorphous silicon film formed with the hard mask layer to form the two solid spacers.

For example, manufacturing a first source/drain electrode, a second source/drain electrode and the gate electrode includes: removing the hard mask layer by anisotropic etching to obtain a plurality of fin structures; filling an insulating medium between adjacent fin structures, such that a shallow trench isolation is formed between the adjacent fin structures; removing a recess of the shallow trench isolation; and etching the fin structure to obtain the first source/drain electrode, the second source/drain electrode and the gate electrode.

For example, etching the fin structure to obtain the first source/drain electrode, the second source/drain electrode and the gate electrode includes: sequentially forming an insulating layer and a silicon layer on a surface of the uppermost silicon material nanosheet layer in the fin structure by deposition; etching the silicon layer to form a dummy gate structure; manufacturing a spacer structure and a source/drain region on two sides of the dummy gate structure; forming the first source/drain electrode and the second source/drain electrode on the source/drain region; removing the dummy gate structure to form a gate electrode region; removing the silicon alloy layer in the stack to release a nanosheet channel; and forming the gate electrode in the gate electrode region by deposition.

For example, manufacturing a spacer structure on two sides of the dummy gate structure includes: depositing a spacer isolation dielectric film; and forming the spacer structure on a surface of the spacer isolation dielectric film by etching.

In S50, a first dielectric constant medium in a first space is removed, where the first space is in the air spacer, and the first space is a space surrounded by an upper surface of the uppermost silicon material nanosheet layer, the gate electrode and any one of the source/drain electrodes.

The first dielectric constant medium is a medium with a dielectric constant greater than a preset value, that is, a High-K medium. The removal of the first dielectric constant medium in the first space may reduce a parasitic capacitance of the GAAFET. In addition, a portion of the first dielectric constant medium covered and protected by the protective layer in the air spacer is not removed, which may reduce an on-resistance of the GAAFET, reduce a delay of a circuit composed of devices, and improve a frequency of the circuit, such as reducing an inverter delay, improving a frequency of a ring oscillator circuit, etc.

In S60, the protective layer is removed.

Specifically, the protective layer may be removed by dry etching or wet etching. The protective layer may be, for example, an amorphous carbon layer. The removal of the protective layer may further reduce a parasitic capacitance of the semiconductor device.

In some embodiments, the manufacturing method may further include: forming an isolation layer by deposition, where the isolation layer covers the air spacer; etching the isolation layer to form a contact hole; and depositing a tungsten material in the contact hole to form a tungsten plug.

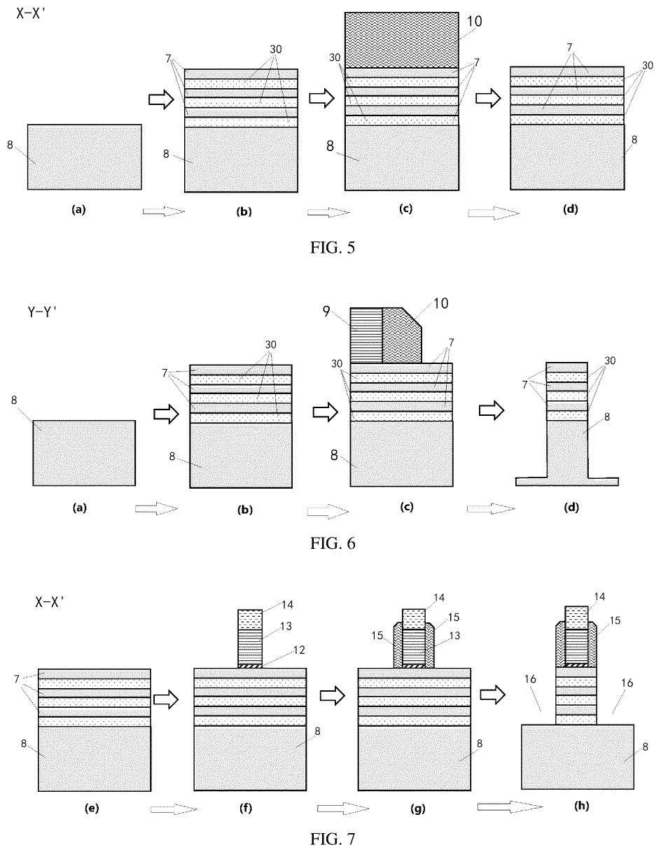

Referring to FIG. 5 to FIG. 16, an embodiment of the present disclosure provides a method of manufacturing a stacked nanosheet gate-all-around field-effect transistor, which may include the following steps (a) to (y).

(a) Silicon substrate doping: well lithography, implantation and annealing are performed.

A substrate 8 made of a silicon material is provided. Well lithography, ion implantation and annealing are sequentially performed on the substrate 8. A process of well lithography is as follows. A surface of the substrate 8 is covered by a photoresist layer, and then a desired pattern is transferred on the photoresist layer through a mask. The photoresist layer is exposed to light, and a portion of the photoresist layer not exposed to light is removed by development, so as to form the desired pattern.

In a process of ion implantation, in a region of the pattern formed by the well lithography, dopants with preset types and preset concentrations are implanted into the silicon substrate by an ion implantation technology. These dopants may change a conductivity of the silicon substrate to form a source region and a drain region.

In a process of annealing the silicon substrate that has undergone the ion implantation, the silicon substrate is heated to a preset temperature, so as to activate the dopant implanted by the ion implantation operation and repair a crystal structure of the silicon substrate implanted with the dopant, thereby reducing a crystal defect of the silicon substrate implanted with the dopant and improving a diffusion degree of the dopant.

(b) A stack is formed by epitaxial growth.

A surface of the annealed structure is cleaned to remove impurities or residues on the surface of the structure, so as to provide a substrate suitable for epitaxial growth of a stack. Then, a plurality of silicon alloy layers 30 and a plurality of nanosheet layers 7 are alternately deposited on the surface of the annealed structure by using technologies such as chemical vapor deposition (CVD) or molecular beam epitaxy (MBE), etc. Specifically, a silicon alloy layer 30 is deposited on the substrate 8. Then, a nanosheet layer 7 is deposited on the silicon alloy layer 30. Next, another silicon alloy layer 30 is deposited on the nanosheet layer, until a preset number of nanosheet layers 7 are obtained. For example, as shown in FIG. 5 and FIG. 6, three layers of nanosheet layers 7 are formed in total. The silicon alloy layer 30 is made of a SiGe material or a SiGa material, and the nanosheet layer 7 is made of a silicon material. A width of the nanosheet layer 7 may be in a range of, for example, 5 nm to 50 nm. A thickness of the nanosheet layer 7 may be in a range of, for example, 3 nm to 20 nm.

In a process of epitaxial growth, the thickness of the stack 7 made of the SiGe material or SiGa material may be adjusted by controlling conditions (such as temperature, air pressure, material ratio in gas phase, etc.) of the epitaxial growth.

(c) Spacer transfer is performed.

Depositing and patterning (photoetching, etching) of a core layer (the core layer is made of an amorphous silicon a-Si material) includes: depositing an amorphous silicon (a-Si) film on the silicon substrate by using technologies such as chemical vapor deposition (CVD) or physical vapor deposition (PVD), etc., so as to form a core layer 9; coating a photoresist on the amorphous silicon film by photolithography, then exposing a specific pattern on the photoresist by using a mask photoetching machine, and finally removing the photoresist in the unexposed region by using processes such as development, so as to form the desired pattern.

Deposition of a hard mask (HM for short) film includes: depositing materials such as silicon nitride (SiNₓ) or silicon oxide (SiO₂) on the amorphous silicon film by using technologies such as chemical vapor deposition (CVD) or physical vapor deposition (PVD), etc., so as to form a hard mask film 10.

Spacer etching includes: patterning the silicon nitride or silicon oxide film by placing a sample in an etching chamber and etching the film with an etching gas (such as hydrogen fluoride), so as to form a desired spacer structure.

Selective removal of the core layer includes: selectively removing the amorphous silicon film (core layer) by using technologies such as chemical solution or plasma etching, etc., and retaining a desired silicon nitride or silicon oxide film, so as to form a key structure of the transistor.

(d) A fin structure is manufactured.

SiGe/Si Fin is anisotropic etched, and the hard mask film 10 is removed, so as to obtain the fin structure.

FIG. 5 shows a schematic sectional view of a structure obtained after the steps (a), (b), (c) and (d) taken along a line X-X′in FIG. 1. FIG. 6 shows a schematic sectional view of a structure obtained after the steps (a), (b), (c) and (d) taken along a line Y-Y′ in FIG. 1.

(e) A shallow trench isolation (STI) is manufactured.

A low-temperature insulating medium layer 11 is deposited (by HARP or FCVD) to fill a gap between the fin structures with an insulating medium, so as to achieve an isolation between the fin structures.

Specifically, the low-temperature insulating medium layer 11 is deposited between and around the fin structures by chemical vapor deposition (CVD). HARP (High Aspect Ratio Process) or FCVD (Flowable Chemical Vapor Deposition) is usually used to achieve uniform deposition in a high aspect ratio structure. This step is intended to fill a gap between the fin structures.

A low-temperature annealing processing makes the low-temperature insulating medium layer 11 more stable by heating, and enhances an adhesion between the low-temperature insulating medium layer 11 and the fin structure.

Specifically, at a controlled low temperature (usually below 500° C.), a heat processing is performed on a current semiconductor structure to promote a rearrangement of a molecular structure of the insulating medium, so as to improve compactness and stability of the insulating medium.

A medium CMP (Chemical Mechanical Polishing) processing is to remove an excess insulating medium from a surface of the fin structure and a surface of the chip, so as to make the surfaces smooth and ensure an accuracy of subsequent process steps.

Specifically, through chemical mechanical polishing, the insulating medium layer on the surface is ground flat by using a mechanical abrasive in a specific chemical solution, so that a height of the fin structure is consistent with a height of the surface of the chip.

The HM (hard mask) and the STI recess are removed to remove residual impurities on the surface of the fin structure, so as to ensure a purity and a stability of the fin structure.

Specifically, residues deposited between the surface of the fin structure and STI (shallow trench isolation) are removed by using a chemical solution or plasma processing technology, such as etching residues or oxide layers, etc. This step may also be performed on an STI region to adjust its surface morphology and properties, so as to ensure a smooth progress of the next process step.

A surface morphology and a depth of the STI recess may be adjusted by etching the STI recess. Dry etching, such as plasma etching or reactive ion etching (RIE), or wet etching, such as chemical mechanical polishing (CMP), may be used in the etching. STI is a common process technology in integrated circuit manufacturing, which is used to isolate different devices on an integrated circuit chip. The STI recess refers to a step of slope retreat in an STI process. In the STI process, a layer of oxide film is first formed on a surface of a silicon wafer, and then a shallow trench is formed on the surface of the silicon wafer by photolithography and etching processes. Next, the shallow trench is filled with an insulating material (usually silicon dioxide SiO₂) to achieve an electrical isolation between the devices. The STI recess means that after filling the insulating material, steps such as polishing, slope retreat, etc. are performed on the insulating material, so that the surface of the insulating material and the surface of the silicon wafer are substantially flat, facilitating a subsequent device fabrication process.

A main purpose of the STI recess step is to make an upper surface of the low-temperature insulating medium layer 11 obtained by filling the insulating material and an upper surface of the silicon substrate 8 located on the same plane, thereby providing a flat surface for a subsequent manufacturing process. This step is very important to ensure that subsequent processes of photoetching, deposition, etching, etc. may be performed accurately, because the flat surface may ensure an accuracy of a photoetching pattern and is also conducive to a fabrication of metal wire connections.

(f) A dummy gate structure is manufactured.

An oxide layer 12 (the oxide layer may be made of a GOX material), a non-single silicon layer 13 (the non-single silicon layer 13 may be, for example, an a-Si or p-Si layer), and a hard mask layer 14 are sequentially deposited.

The step of depositing the oxide layer 12 specifically includes: depositing an insulating layer (usually silicon dioxide SiO₂) on the surface of the substrate by using a chemical vapor deposition (CVD) or physical vapor deposition (PVD) technology, so as to obtain the oxide layer 12. Parameters such as temperature, pressure, gas flow rate, etc. in the deposition process are controlled to obtain the oxide layer with a desired thickness.

The step of depositing the non-single silicon layer 13 (amorphous silicon a-Si or polysilicon p-Si) may specifically include: depositing an amorphous silicon (a-Si) or polysilicon (p-Si) layer on the oxide layer 12 by using a CVD or PVD technology, so as to form the non-single silicon layer 13. The non-single silicon layer 13 is used as a main portion of the dummy gate structure. Parameters such as temperature, pressure, gas flow rate, etc. in the deposition process are controlled to obtain the silicon layer with a desired thickness.

The operation process of forming the hard mask layer 14 by deposition may include: depositing the hard mask layer 14 on the silicon layer by using a CVD or PVD technology, so as to protect a gate electrode structure. Parameters such as temperature, pressure, gas flow rate, etc. in the deposition process are controlled to obtain the hard mask layer with a desired thickness. The hard mask layer may be abbreviated as HM (hard mask).

The process of gate electrode photoetching and etching is as follows. A gate electrode pattern is designed on a mask plate of a photoresist layer, then the pattern is exposed on the photoresist layer by a photoetching machine. The exposed region of the photoresist layer is developed to dissolve or remove it, so as to form the photoresist layer with the gate electrode pattern. The non-single silicon layer 13 and the oxide layer 12 are etched by using the pattern on the photoresist layer as a mask through dry etching (such as plasma etching) or wet etching (such as chemical etching). The photoresist layer is cleaned and removed, and the gate electrode pattern is exposed, so as to form a final dummy gate structure. The dummy gate structure is used to reserve a space for the subsequent formation of the gate electrode.

(g) A spacer isolation dielectric film is formed by deposition.

Deposition of the isolation dielectric film includes: uniformly depositing an isolation dielectric film on the entire surface by using a chemical vapor deposition (CVD) or physical vapor deposition (PVD) technology. Parameters such as temperature, pressure, gas flow rate, etc. in the deposition process are controlled to obtain the dielectric film with a desired thickness.

Spacer formation includes: forming a spacer structure 15 on a surface of the deposited dielectric film by processes such as photoresist deposition, photoetching, development and etching.

Etching of the spacer isolation dielectric film includes: covering a photoresist on the spacer isolation dielectric film; exposing a desired pattern on the photoresist layer through the photoetching machine, where the pattern design includes a desired spacer shape; performing a development process on an exposed region in the photoresist layer to dissolve or remove the exposed region, so as to form a photoresist pattern of the spacer isolation dielectric film; and etching a surface of the dielectric film by using the photoresist pattern as a mask, so as to form the spacer structure 15.

Dry etching or wet etching may be used in the etching process, depending on material and process requirements.

The photoresist layer is cleaned and removed to expose the finally formed spacer structure 15.

Through the above-mentioned steps, the deposition and etching operations of the spacer isolation dielectric film are completed, so as to form the desired spacer structure 15. The spacer structure 15 may be used to isolate and control an electrical performance between electronic components in a process of manufacturing an integrated circuit.

(h) A source/drain region 16 is obtained by etching the fin structure.

The fin structure is covered by a photoresist, and a desired pattern is exposed on the photoresist layer through the photoetching machine. The pattern includes a position and a shape of a desired source/drain region.

A development process is performed on an exposed region in the photoresist layer to dissolve or remove the exposed region, so as to form a photoresist pattern of the source/drain region. The fin structure region is etched by using the photoresist pattern as a mask, so as to form the source/drain region 16.

Through the above-mentioned steps, the operation of obtaining the source/drain region 16 by etching the fin structure is completed, so as to form the desired source/drain region 16. The source/drain region 16 is used to connect a source electrode and a drain electrode of the transistor, so as to achieve an injection and an output of a current, thereby controlling a working state of the transistor.

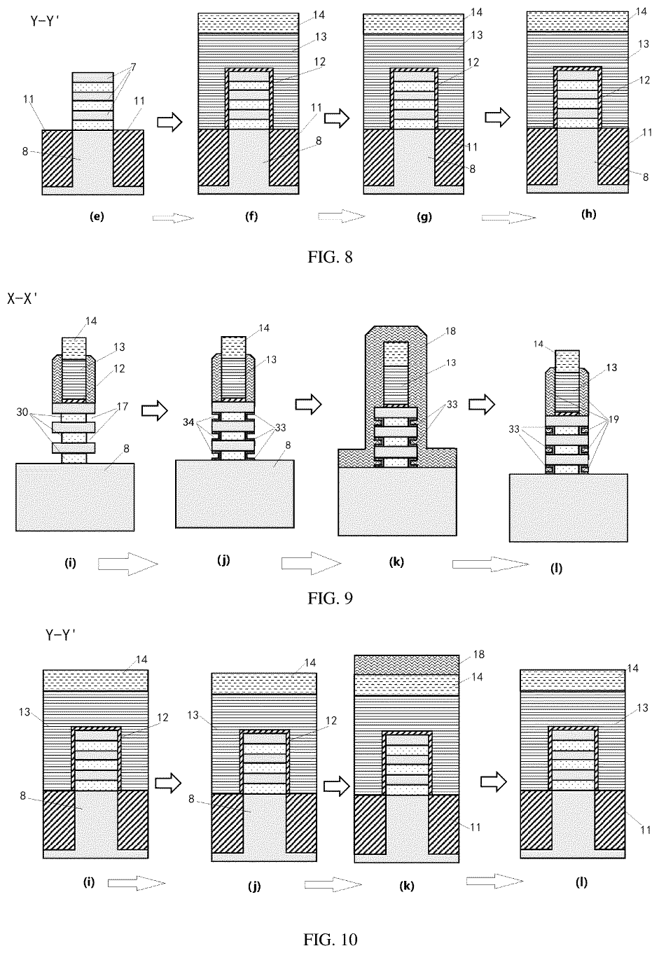

FIG. 7 shows a schematic sectional view of a structure obtained after the steps (e), (f), (g) and (h) taken along a line X-X′ in FIG. 1. FIG. 8 shows a schematic sectional view of a structure obtained after the steps (e), (f), (g) and (h) taken along a line Y-Y′ in FIG. 1.

(i) A first pull-back cavity 17 is formed by etching the silicon alloy layer 30.

When etching the silicon alloy layer 30, the silicon alloy layer 30 is etched by using the photoresist pattern as a mask, so as to form the first pull-back cavity 17. Dry etching or wet etching may be used in the etching process, depending on material and process requirements.

The silicon alloy layer 30 is made of a SiGe material or a SiGa material. Specific electrical characteristics of the device may be achieved through the pull-back cavity 17.

(j) An amorphous carbon material (or another material) is deposited to form a protective layer 33 (a thickness of the protective layer 33 is less than half of an etching depth of SiGe), and the protective layer 33 is anisotropic etched to form a second pull-back cavity 34.

The amorphous carbon layer may be manufactured by technologies such as chemical vapor deposition (CVD) or physical vapor deposition (PVD), etc. In the CVD, carbon source gas (such as methane) may be decomposed and deposited on the substrate to form the amorphous carbon layer. In the PVD, carbon atoms may be deposited on the substrate by an evaporation or sputtering method, so as to form the amorphous carbon layer.

(k) An inner spacer isolation dielectric film 18 is formed by depositing a SiNx material.

The inner spacer isolation dielectric film 18 is formed on an inner spacer surface of a SiGe pull-back cavity by deposition, using deposition technologies such as chemical vapor deposition (CVD) or physical vapor deposition (PVD), etc. A common isolation dielectric material includes silicon nitride (Si₃N₄) or silicon oxide (SiO₂), and the selection for the material depends on process and device requirements.

(1) The inner spacer isolation dielectric film 18 is etched.

The inner spacer isolation dielectric film 18 is etched to obtain a film remaining portion 19.

(m) The epitaxial layer 20 is obtained by source/drain epitaxy.

Appropriate materials are selected for source/drain epitaxy of P/NMOS devices, respectively. For a P-type MOS (PMOS), the SiGe material may be used for epitaxy; for an N-type MOS (NMOS), the silicon (Si) material may be used for epitaxy. In the epitaxial process, a corresponding material is deposited in the source/drain region by using technologies such as chemical vapor deposition (CVD) or molecular beam epitaxy (MBE), etc.

FIG. 9 shows a schematic sectional view of a structure obtained after the steps (i), (j), (k) and (1) taken along a line X-X′ in FIG. 1. FIG. 10 shows a schematic sectional view of a structure obtained after the steps (i), (j), (k) and (1) taken along a line Y-Y′ in FIG. 1.

(n) Source/drain doping is performed.

Etching of an inner spacer includes: etching an inner spacer surface of the SiGe pull-back cavity by using technologies such as chemical corrosion or plasma etching, etc. The purpose of this step is to remove the SiGe material, so as to form a flat inner spacer surface.

Source/drain doping includes: respectively performing source/drain doping on the PMOS/NMOS devices to obtain a doped layer 21. For the PMOS, the source/drain region is doped using a P-type dopant (such as boron); for the NMOS, the source/drain region is doped using an N-type dopant (such as arsenic or phosphorus). In the doping process, the dopant may be implanted into the source/drain region by using technologies such as ion implantation or molecular beam epitaxy, etc.

(o) An ILD layer is deposited and a planarization process is performed.

Deposition of the ILD dielectric layer includes: depositing an ILD dielectric layer 22 on a surface of the current semiconductor structure by using technologies such as chemical vapor deposition (CVD) or physical vapor deposition (PVD), etc. A dielectric material of the ILD dielectric layer 22 includes silicon dioxide (SiO₂), silicon nitride (Si₃N₄) or aluminum oxide (Al₂O₃). The deposited dielectric has characteristics of flatness, uniformity and compactness. The planarization process is performed on the deposited dielectric, so as to ensure a flat surface of the dielectric layer and avoid an influence on subsequent processes.

POP CMP (Planar Chemical Mechanical Polishing) includes: polishing the surface of the current semiconductor structure with a rotating polishing disc and an abrasive solution by using the chemical mechanical polishing (CMP) process. This process is intended to smooth the surface of the dielectric layer and eliminate a height difference. Through the above-mentioned steps, the operations of ILD dielectric layer deposition and POP CMP are completed, which are helpful to improve a flatness of the surface of the semiconductor structure and provide a good foundation for subsequent processes.

(p) The dummy gate structure is removed to form a gate electrode reserved region 23, where the dummy gate structure is the above-mentioned non-single silicon layer 13.

A wet chemical corrosion method may be used in this step. Specifically, the current semiconductor structure is soaked in an appropriate corrosion solution, such as a hydrofluoric acid (HF) solution or a mixed acid solution, so as to remove the dummy gate structure.

A dry etching method may also be used in this step. Specifically, the current semiconductor structure may be placed in a reaction chamber, and the dummy gate structure may be removed under an action of high-energy gas by using a plasma etching process.

Time and conditions of etching or corrosion are controlled to ensure that only the dummy gate structure is removed without damaging other regions.

(q) The nanosheet channel is released.

A wet corrosion method may be used in this step. Specifically, the current semiconductor structure is soaked in an appropriate corrosion solution, such as the hydrofluoric acid (HF) solution or the mixed acid solution, so as to remove a dielectric material beside the nanosheet channel. That is, a remaining portion of the silicon alloy layer 30 is removed to release the nanosheet channel.

A dry etching method may also be used in this step. Specifically, the current semiconductor structure may be placed in a reaction chamber, and a dielectric material around the nanosheet channel may be removed under an action of high-energy gas, by using a plasma etching process. That is, a remaining portion of the silicon alloy layer 30 is removed to release the nanosheet channel. A gap region 24 is formed after the remaining portion of the silicon alloy layer 30 is completely removed.

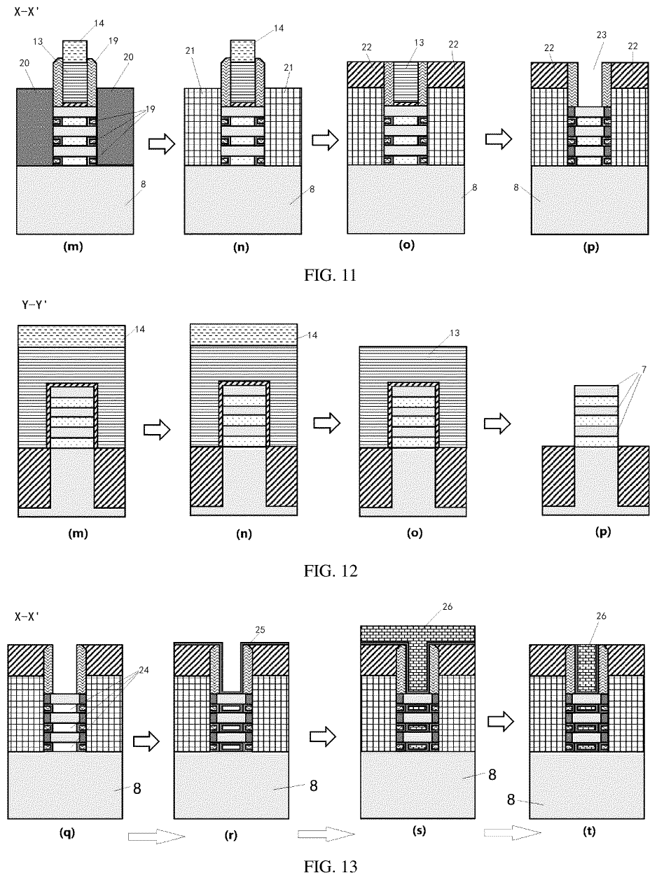

FIG. 11 shows a schematic sectional view of a structure obtained after the steps (m), (n), (o) and (p) taken along a line X-X′ in FIG. 1. FIG. 12 shows a schematic sectional view of a structure obtained after the steps (m), (n), (o) and (p) taken along a line Y-Y′ in FIG. 1.

(r) An amorphous silicon layer, a mixed layer 32 and a polysilicon work function layer 25 are formed by deposition.

The amorphous silicon layer 31 is formed on the upper surface of the substrate 8 by deposition.

The mixed layer 32 includes an interlayer, a High-K layer and a first barrier insertion layer from inside to outside. The interlayer wraps the silicon material nanosheet layer 7, the High-K layer wraps the interlayer, and the first barrier insertion layer wraps the High-K layer.

Deposition of the interlayer (IL for short) includes: depositing an insulating layer (such as SiO₂) on a surface of the silicon material nanosheet layer 7. The insulating layer is called the interlayer and is used to isolate different metal layers or functional layers.

Deposition of the High-K (HK for short) material layer includes: depositing a High-K material (such as HfO₂ or ZrO₂) to replace traditional SiO₂ as a gate dielectric layer, so as to reduce a leakage current and a power consumption of the transistor.

Deposition of the first barrier insertion (Barrier-I for short) layer includes: depositing a barrier insertion layer (a material of the barrier insertion layer may be, for example, TiN or TaN), so as to prevent an impurity diffusion and improve a reliability of an electronic device.

Deposition of the polysilicon work function layer 25 (P-WFL for short) includes: depositing a polysilicon work function layer to adjust a work function of the gate electrode of the transistor, so as to control a performance of the electronic device.

The photoresist is coated on the surface of the current semiconductor structure. The photoresist on the chip is exposed using the photoetching machine, and an image is formed on the photoresist according to a designed photoetching pattern. The exposed photoresist is developed, and an unexposed photoresist is removed, so as to form a structure of the photoetching pattern.

A corrosion operation includes dry corrosion and wet corrosion. The dry corrosion is to accurately etch the IL/HK/Barrier-I/P-WFL layers according to the photoetching pattern by using a plasma etching technology, so as to form a desired structure. The wet corrosion is to wet etch the IL/HK/Barrier-I/P-WFL layers using a chemical solution, so as to achieve a specific shape and size.

(s) A metal gate (MG) is manufactured.

Deposition of an N-type polysilicon work function layer (N-WFL for short) includes: depositing an N-type polysilicon work function layer on the surface of the current semiconductor structure to adjust functional parameters of the gate electrode of the transistor. This layer is usually used to control the conductive property of the stacked nanosheet gate-all-around field-effect transistor (FET).

Deposition of a second barrier insertion (Barrier-II) layer includes: depositing the second barrier insertion layer to prevent the impurity diffusion and improve the reliability of the electronic device. An isolation layer is usually formed between the second barrier insertion layer and the N-WFL layer.

A tungsten layer 26 is deposited on the current semiconductor structure as a metal gate. The tungsten layer 26 may be filled and connected to various structures, such as interconnection lines or filled resistors.

(t) CMP is performed on the metal gate.

CMP refers to Chemical Mechanical Polishing, which is a process of flattening and smoothing a surface of a semiconductor product by a method of combining mechanics and chemistry. CMP is widely used in semiconductor manufacturing, especially to form a flat connection between a metal layer and an insulating layer. After polishing the deposited tungsten layer 26, an upper surface of the obtained metal gate is flush with an upper surface of the ILD dielectric layer 22.

(u) Spacer corrosion is performed.

After CMP is performed on the metal gate, a spacer SiN material is corroded to remove the spacer SiN medium, so as to form the air spacer 27. Air has the lowest dielectric constant, so the air spacer 27 may greatly reduce the parasitic capacitance of the stacked nanosheet gate-all-around field-effect transistor. A first space 35 is a space in the air spacer 27, which is surrounded by an upper surface of the uppermost silicon material nanosheet layer, the gate electrode 3, and any one of the source/drain electrodes. That is, the first space 35 is a portion of the air spacer 27. The uppermost silicon material nanosheet layer is a silicon material nanosheet layer farthest from the upper surface of the substrate 8 in a direction perpendicular to the upper surface of the substrate 8. In addition to the first space 35, the air spacer 27 further includes a space located in the second pull-back cavity 34.

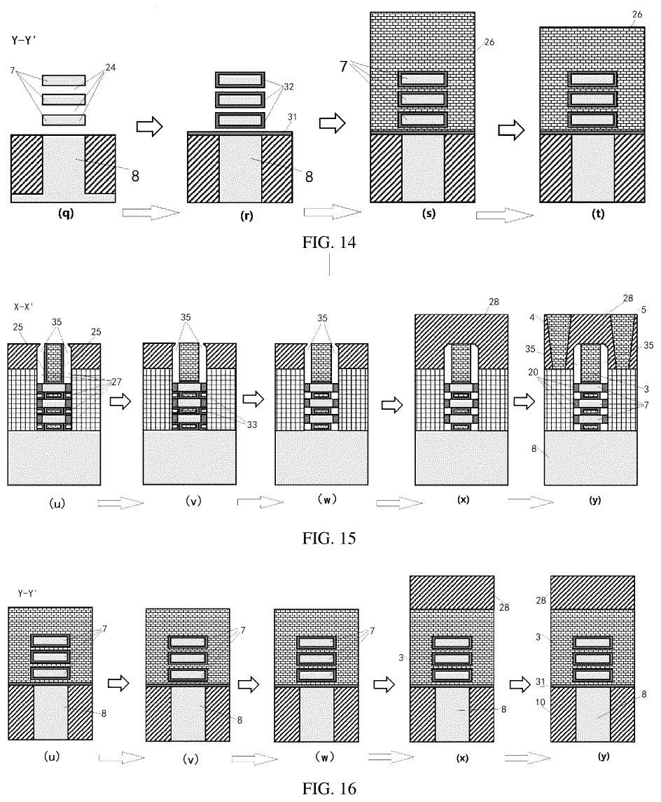

FIG. 13 shows a schematic sectional view of a structure obtained after the steps (q), (r), (s) and (t) taken along a line X-X′in FIG. 1. FIG. 14 shows a schematic sectional view of a structure obtained after the steps (q), (r), (s) and (t) taken along a line Y-Y′ in FIG. 1.

(v) The High-K layer is removed by corrosion.

After the air spacer 27 is formed, a High-K layer in the first space 35 is removed by selective atomic-level etching (ALE). The High-K medium in the first space 35 is completely removed, so that the parasitic capacitance of the device may be further greatly reduced.

A HfO₂ material with a High-K value is still provided between the gate electrode and the source/drain electrode, which may cause a large parasitic capacitance of the device. The selective atomic-level etching is performed to selectively remove the HfO₂ material with the High-K value on two sides of the metal gate, and all the High-K medium in the first space 35 is removed, thereby greatly reducing the parasitic capacitance of the device.

The selective atomic-level etching includes: accurately controlling an etching process by an alternating process of atomic layer deposition (ALD) and atomic layer etching (ALE) using a specific etching gas, such as hydrogen fluoride (HF). In each cycle, the etching gas may react with a High-K material to selectively remove the High-K layer on two sides of the metal gate.

Circulation of the etching process includes: repeating the cycle of ALD and ALE until the High-K layer on two sides of the metal gate is completely removed and a metal material between the source/drain electrode and the gate electrode is exposed; and stopping the etching when a desired etching depth is achieved or the High-K layer is completely removed.

(w) The protective layer 33 composed of the amorphous carbon layer is removed.

Specifically, the amorphous carbon layer may be removed by dry etching or wet etching. The protective layer 33 composed of the amorphous carbon layer may be removed, which may further reduce the parasitic capacitance of the semiconductor device.

The dry etching includes plasma etching and electron beam etching. The plasma etching includes oxygen plasma etching and reactive ion etching.

The oxygen plasma etching includes that: oxygen plasma reacts to generate active oxygen atoms and ions, which react with carbon in the amorphous carbon layer to generate carbon dioxide and water, thereby removing the carbon layer.

The reactive ion etching (RIE) includes that: in the RIE, oxygen is mixed with other gases (such as fluoride), and the amorphous carbon layer is etched by high-energy ion bombardment and chemical reaction.

The electron beam etching includes: directly bombarding the amorphous carbon layer by using high-energy electron beams, so as to decompose and remove the amorphous carbon layer. This method is usually used for fine patterning etching.

The wet etching includes: chemical solution etching. Specifically, the amorphous carbon layer is etched using a solution of strong oxidant (such as hydrogen peroxide, sulfuric acid, nitric acid, etc.). These chemical solutions may oxidize carbon to generate soluble products (such as carbon dioxide, carbonate, etc.), thereby removing the carbon layer.

(x) An ILD layer 28 is formed by deposition.

Operation steps of dielectric deposition of the ILD layer 28 are as follows.

Chemical vapor deposition (CVD) includes: placing the substrate in a reaction chamber, introducing pre-prepared chemical gas required for the deposition of the ILD dielectric layer 28, and depositing a desired insulating layer material on the surface of the chip through a thermochemical reaction.

Control of deposition parameters includes: controlling parameters such as deposition temperature, pressure, gas flow rate, etc. so as to ensure that a uniform and dense insulating layer is deposited.

Stop of the deposition includes: after achieving a desired deposition thickness, stopping the deposition process and taking out the chip.

Operation steps of dielectric polishing include: preparing the chip which has undergone the deposition of the ILD dielectric layer 28, and ensuring that its surface is clean and dust-free; putting the chip in the CMP equipment, and gradually removing an excess dielectric material through mechanical polishing and chemical dissolution by a chemical mechanical polishing (CMP) method, so as to make the surface smooth.

Control of polishing parameters includes: controlling a pressure, a speed, an abrasive particle size and a chemical solution ratio during polishing, so as to ensure an accurate control of polishing process and a surface quality.

After the polishing is completed, the chip is thoroughly cleaned to remove residual abrasives and residual chemical solutions, and the surface is inspected, so as to meet desired flatness and quality requirements.

(y) Contact and interconnection are performed.

Operation steps of contact hole photoetching and etching include: preparing the chip that requires photoetching and etching; depositing a photoresist layer on the surface of the chip; placing the chip in the photoetching machine; irradiating a pre-designed pattern to chemically change a portion of the photoresist, so as to form the photoetching pattern; placing the chip in an etching device; and removing a part of dielectric material not covered by the photoresist by using chemical vapor etching (CPE) or physical vapor etching (PPE), thereby forming the contact hole.

Operation steps of hole silicide formation include: preparing the chip with the contact hole; depositing a silicon material layer in the contact hole; removing a part of dielectric material not protected by silicide by using the chemical vapor etching (CPE) or physical vapor etching (PPE), thereby forming the hole silicide. After the etching, the chip is thoroughly cleaned to remove residual etching gas and residual impurities, and the hole silicide is inspected to meet desired quality requirements.

Manufacturing of the tungsten plug (W-Plug) includes: preparing the chip with the hole silicide; depositing a tungsten material layer in the hole silicide; removing a part of dielectric material not protected by the tungsten material by using the chemical vapor etching (CPE) or physical vapor etching (PPE), thereby forming the W-Plug.

FIG. 15 shows a schematic sectional view of a structure obtained after the steps (u), (v), (w), (x) and (y) taken along a line X-X′in FIG. 1. FIG. 16 shows a schematic sectional view of a structure obtained after the steps (u), (v), (w), (x) and (y) taken along a line Y-Y′ in FIG. 1.

In some examples, an nMOS device is manufactured on a P-type bulk silicon substrate, and a pMOS device is manufactured on an N-type bulk silicon substrate. A source/drain epitaxy of the nMOS device is Si doped P, and a source/drain epitaxy of the pMOS device is SiGe doped B. An STI oxide isolation is used. No High-K layer is provided on two sides of the metal gate. A corrosion spacer SiN, takes HfO₂, SiO₂ and Si as etching stop layers.

In some examples, the protective layer 33 composed of the amorphous carbon layer or other materials with the same function is used to protect the High-K material at the inner spacer, and the High-K layer on two sides of the metal gate is removed by selective atomic-level etching (ALE), which may further reduce a parasitic capacitance of the air spacer stacked nanosheet GAA device and improve a working speed of the device and the circuit. A thin protective layer composed of the amorphous carbon material or other materials is first deposited, and the spacer material is removed after performing the High-K metal gate polishing (HKMG CMP) operation, the High-K material at the spacer position is peeled by atomic-level etching, and then the protective layer is removed. The part of the High-K material protected by the protective layer 33 is not removed.

The specific implementation method is as follows. After the SiGe material is etched, a sacrificial layer material is deposited. In this step, amorphous carbon or other suitable materials may be selected for deposition, and a thickness is less than half of an etching depth of SiGe. Then, an inner spacer is formed, and High-K deposition is performed after the nanosheet layers are released. After the air spacer is formed, corresponding to the process step (u), the High-K layer on two sides of the metal gate is removed by selective atomic-level etching (ALE), and then the protective layer is removed, so as to form a stacked nanosheet transistor structure in which the High-K material at the spacer position is removed, thereby reducing the parasitic capacitance of the device.

Before the protective layer 33 is removed, in addition to the first space 35, the air spacer 27 further includes a space located in the second pull-back cavity 34. The second pull-back cavity 34 is formed by recessing the protective layer 33, and the part of High-K material protected by the protective layer 33 is not removed. In this way, such part of High-K material may increase a driving current of the field-effect transistor and reduce an on-resistance of the field-effect transistor, thereby optimizing a performance of the circuit composed of the field-effect transistor, such as reducing an inverter delay and increasing a frequency of a ring oscillator circuit.

Another embodiment of the present disclosure provides a stacked nanosheet gate-all-around field-effect transistor, which is manufactured by the manufacturing method in any one of embodiments of the present disclosure. The stacked nanosheet gate-all-around field-effect transistor includes: a substrate; a first source/drain electrode located on the substrate and a second source/drain electrode located on the substrate; a gate electrode located on the substrate and located between the first source/drain electrode and the second source/drain electrode, where an air spacer is formed between the gate electrode and the first source/drain electrode and between the gate electrode and the second source/drain electrode; and a plurality of silicon material nanosheet layers spaced apart from each other in the gate electrode, where each of the plurality of silicon material nanosheet layers is connected to the first source/drain electrode and the second source/drain electrode, and each of the plurality of silicon material nanosheet layers is parallel to an upper surface of the substrate.

The technical solution provided by one of the aspects of the embodiments of the present disclosure may include the following advantages.

The method of manufacturing the stacked nanosheet gate-all-around field-effect transistor provided by the embodiments of the present disclosure includes: forming a stack on a substrate by deposition, where the stack includes a plurality of silicon material nanosheet layers and a plurality of silicon alloy layers alternately stacked; etching each of the plurality of silicon alloy layers to form a first pull-back cavity, where the first pull-back cavity is located between two adjacent silicon material nanosheet layers; manufacturing a protective layer in the first pull-back cavity, where the protective layer covers an inner surface of the first pull-back cavity, and the protective layer is recessed to form a second pull-back cavity; manufacturing a gate electrode located on the substrate and two source/drain electrodes located on the substrate based on the second pull-back cavity, where an air spacer is formed between the gate electrode and any one of the source/drain electrodes; and removing a first dielectric constant medium in a first space, where the first space is in the air spacer, and the first space is a space surrounded by an upper surface of the uppermost silicon material nanosheet layer, the gate electrode and any one of the source/drain electrodes. The manufactured stacked nanosheet gate-all-around field-effect transistor has a simple structure, may greatly reduce a parasitic capacitance, and may improve a working efficiency of a circuit in which the stacked nanosheet gate-all-around field-effect transistor is located.

The above-mentioned descriptions of various embodiments tend to emphasize differences between the various embodiments, and their same or similar features may be referenced with each other. For the sake of brevity, the details thereof will not be repeated here.

It should be understood that although the steps in the flowchart of the accompanying drawings are shown in sequence as indicated by the arrows, these steps are not necessarily executed in sequence as indicated by the arrows. Unless explicitly stated herein, the execution of these steps is not strictly limited in the sequence, and these steps may be executed in other sequences. Moreover, at least a part of the steps in the flowchart of the accompanying drawings may include a plurality of sub-steps or a plurality of stages. These sub-steps or stages may not necessarily be completed at the same time, but may be executed at different times. These sub-steps or stages may not necessarily be performed in sequence, but may be executed in turn or alternatively with other steps or at least a part of sub-steps or stages of other steps.

The above-mentioned embodiments only express the implementation method of the present disclosure, and the descriptions thereof are specific and detailed, but they may not be understood as limiting the scope of the present disclosure. It should be pointed out that without departing from the concept of the present disclosure, those skilled in the art may make several modifications and improvements, and these modifications and improvements should fall within the scope of protection of the present disclosure. Therefore, the scope of protection of the present disclosure should be based on the appended claims.

What is claimed is:

1. A method of manufacturing a stacked nanosheet gate-all-around field-effect transistor, comprising:
forming a stack on a substrate by deposition, wherein the stack comprises a plurality of silicon material nanosheet layers and a plurality of silicon alloy layers alternately stacked;
etching each of the plurality of silicon alloy layers to form a first pull-back cavity, wherein the first pull-back cavity is located between two adjacent silicon material nanosheet layers;
manufacturing a protective layer in the first pull-back cavity, wherein the protective layer covers an inner surface of the first pull-back cavity, and the protective layer is recessed to form a second pull-back cavity;
manufacturing a gate electrode located on the substrate and two source/drain electrodes located on the substrate based on the second pull-back cavity, wherein an air spacer is formed between the gate electrode and any one of the source/drain electrodes; and
removing a first dielectric constant medium in a first space, wherein the first space is in the air spacer, and the first space is a space surrounded by an upper surface of the uppermost silicon material nanosheet layer, the gate electrode and any one of the source/drain electrodes.

2. The method according to claim 1, wherein the forming a stack on a substrate by deposition comprises:
providing a silicon substrate, and sequentially performing well lithography, ion implantation and annealing on the silicon substrate; and
forming the stack on a surface of the annealed silicon substrate by deposition.

3. The method according to claim 1, wherein the manufacturing a gate electrode located on the substrate and two source/drain electrodes located on the substrate based on the second pull-back cavity comprises:
manufacturing two solid spacers, a first source/drain electrode, a second source/drain electrode and the gate electrode, wherein the plurality of silicon material nanosheet layers are located between the two solid spacers, and the second pull-back cavity is filled with a corresponding solid spacer; and
removing the two solid spacers to form two air spacers.

4. The method according to claim 3, wherein the manufacturing two solid spacers comprises:
depositing an amorphous silicon film on the substrate;
forming a target pattern on the amorphous silicon film by photoetching;
forming a hard mask layer on the amorphous silicon film with the target pattern by deposition; and
etching the amorphous silicon film formed with the hard mask layer to form the two solid spacers.

5. The method according to claim 4, wherein the manufacturing a first source/drain electrode, a second source/drain electrode and the gate electrode comprises:
removing the hard mask layer by anisotropic etching to obtain a plurality of fin structures;
filling an insulating medium between adjacent fin structures, such that a shallow trench isolation is formed between the adjacent fin structures;
removing a recess of the shallow trench isolation; and
etching the fin structure to obtain the first source/drain electrode, the second source/drain electrode and the gate electrode.

6. The method according to claim 5, wherein the etching the fin structure to obtain the first source/drain electrode, the second source/drain electrode and the gate electrode comprises:
sequentially forming an insulating layer and a silicon layer on a surface of the uppermost silicon material nanosheet layer in the fin structure by deposition;
etching the silicon layer to form a dummy gate structure;
manufacturing a spacer structure and a source/drain region on two sides of the dummy gate structure;
forming the first source/drain electrode and the second source/drain electrode on the source/drain region;
removing the dummy gate structure to form a gate electrode region;
removing the silicon alloy layer in the stack to release a nanosheet channel; and
forming the gate electrode in the gate electrode region by deposition.

7. The method according to claim 6, wherein the manufacturing a spacer structure on two sides of the dummy gate structure comprises:
depositing a spacer isolation dielectric film; and
forming the spacer structure on a surface of the spacer isolation dielectric film by etching.

8. The method according to claim 1, further comprising:
removing the protective layer.

9. The method according to claim 8, further comprising:
forming an isolation layer by deposition, wherein the isolation layer covers the air spacer;
etching the isolation layer to form a contact hole; and
depositing a tungsten material in the contact hole to form a tungsten plug.

10. The method according to claim 1, wherein the protective layer is an amorphous carbon layer.

11. A stacked nanosheet gate-all-around field-effect transistor, manufactured by the method according to claim 1, comprising:
a substrate;
a first source/drain electrode located on the substrate and a second source/drain electrode located on the substrate;
a gate electrode located on the substrate and located between the first source/drain electrode and the second source/drain electrode, wherein an air spacer is formed between the gate electrode and the first source/drain electrode and between the gate electrode and the second source/drain electrode; and
a plurality of silicon material nanosheet layers spaced apart from each other in the gate electrode, wherein each of the plurality of silicon material nanosheet layers is connected to the first source/drain electrode and the second source/drain electrode, and each of the plurality of silicon material nanosheet layers is parallel to an upper surface of the substrate.
